(19) United States
(12) Patent Application Publication
(10) Pub. No.: US 2025/0374512 A1
(43) Pub. Date: Dec. 4, 2025

(54) HYBRID GAIN CELLS HAVING BACK-END-OF-LINE (BEOL) FIELD EFFECT TRANSITORS (FETs)

(71) Applicant: Taiwan Semiconductor Manufacturing Company, Ltd., Hsin-Chu (TW)

(72) Inventors: Hung-Li Chiang, Taipei City (TW); Carlo Gilardi, Hsinchu (TW); Iuliana Radu, Hsinchu County (TW)

(21) Appl. No.: 18/889,812

(22) Filed: Sep. 19, 2024

Related U.S. Application Data
(60) Provisional application No. 63/655,194, filed on Jun. 3, 2024.

(51) Int. Cl. H10B 12/00

(52) U.S. Cl. CPC H10B 12/00

(57) ABSTRACT

One aspect of the present disclosure pertains to a device. The device includes a first transistor and a second transistor coupled in series; a third transistor and a fourth transistor coupled in series; and a fifth transistor, a first terminal of the fifth transistor being coupled to each of a first terminal of the first transistor and a first terminal of the second transistor, and a control terminal of the fifth transistor being coupled to a second terminal of the second transistor at a storage node. A control terminal of the fourth transistor is coupled to the storage node, and at least one of the first to fifth transistors is located in a layer above another one of the first to fifth transistors.

### PRIORITY DATA

This application claims the benefit of U.S. Provisional App. No. 63/655,194, filed Jun. 3, 2024, which is hereby incorporated by reference in its entirety.

### BACKGROUND

Gain cell embedded memory (e.g., GC-eDRAM) has emerged as a promising candidate to replace traditional SRAM (e.g., 6-transistor bit cell SRAM) in certain applications. Gain cell embedded memory are smaller compared to SRAM, and their two-ported operation also allows for non-destructive reads. Further, gain cell embedded memory may operate at lower power and at lower current leakage levels compared to SRAM (e.g., due to less leakage paths). Although SRAM still has certain advantages such as faster access speeds and robust static data retention, SRAM cells consumes a higher power budget and are relatively large which prevents keeping up with device scaling.

However, gain cell embedded memory still has room for improvements, especially in the realm of data retention, threshold voltage variability, memory access time, and device footprint reduction. Therefore, although existing gain cell designs and structures have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIGS. 1A-1E illustrate gain cell circuits in various configurations, according to embodiments of the present disclosure.

FIG. 2 illustrates a gain cell circuit having 5 transistors (5T) with 4 front-end-of-line (FEOL) transistors and 1 back-end-of-line (BEOL) transistor, according to an embodiment of the present disclosure.

FIGS. 3A-3B illustrate simplified cross-sections of the gain cell circuit of FIG. 2, according to an embodiment of the present disclosure.

FIGS. 4A-4D illustrate top view layouts of a gain cell circuit at different layer levels (e.g., different layer levels of the gain cell circuit of FIG. 2 with cross-section of FIGS. 3A-3B), according to an embodiment of the present disclosure.

FIG. 5 illustrates a perspective view of the gain cell circuit of FIGS. 4A-4D, according to an embodiment of the present disclosure.

FIG. 6 illustrates a perspective view of the gain cell circuit of FIGS. 4A-4D, according to another embodiment of the present disclosure.

FIG. 7 illustrates a gain cell circuit having 5 transistors (5T) with 2 front-end-of-line (FEOL) transistors and 3 back-end-of-line (BEOL) transistor, according to an embodiment of the present disclosure.

FIG. 8 illustrate simplified cross-sections of the gain cell circuit of FIG. 7, according to an embodiment of the present disclosure.

FIG. 9 illustrate simplified cross-sections of the gain cell circuit of FIG. 7, according to another embodiment of the present disclosure.

FIG. 10 illustrates a gain cell circuit having 5 transistors (5T) with 2 front-end-of-line (FEOL) transistors and 3 back-end-of-line (BEOL) transistor, according to another embodiment of the present disclosure.

FIG. 11 illustrates a simplified cross-section of the gain cell circuit of FIG. 10, according to an embodiment of the present disclosure.

FIGS. 12A-12F illustrate perspective views of a gain cell circuit (e.g., gain cell circuit of FIG. 10 with cross-section of FIG. 11) and with different layer levels highlighted, according to an embodiment of the present disclosure.

FIGS. 13A-13F illustrate top view layouts of a gain cell circuit at the different layer levels highlighted in FIGS. 12A-12F, respectively, according to an embodiment of the present disclosure.

FIGS. 14A-14B illustrate a generalized gain cell circuit configuration having 5 transistors (5T) with 2 front-end-of-line (FEOL) transistors and 3 back-end-of-line (BEOL) transistor, according to an embodiment of the present disclosure.

FIG. 15 illustrates a gain cell circuit having 5 transistors (5T) with 2 front-end-of-line (FEOL) transistors and 3 back-end-of-line (BEOL) transistor, according to another embodiment of the present disclosure.

FIG. 16 illustrates operations of a gain cell, according to an embodiment of the present disclosure.

FIG. 17 illustrates a memory system having an array of 5T gain cells, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to memory devices and structures, and particularly to gain cell circuits having 5 transistors (5T) with at least one of the 5 transistors formed in the back-end-of-line (BEOL). Although more than one BEOL transistor in the 5T gain cell is possible, at least one of the BEOL transistor is a feedback transistor part of a feedback loop coupled to the storage node to improve storage node charge retention. The feedback loop includes the feedback transistor, a read transistor, and a write transistor, where each of these transistors have terminals connected to the storage node. The feedback transistor formed as a BEOL transistor leverages several advantages. The BEOL transistor allows increase in transistor total capacitance with respect to front-end-of-line (FEOL) transistors due to larger device area (which improves storage node charge retention) and enables a 5T circuit to fit within a 4T footprint, leading to area benefits. Further, the BEOL transistor is not used to write/read and therefore would not incur performance penalties to driving current and threshold voltage variability. Instead, it is merely used to reinforce stored bit polarity when write operation is off. In this way, reliability and variability concerns will not be an issue. The BEOL transistor can be realized with BEOL-compatible materials (e.g., amorphous oxides, two-dimensional materials, carbon nanotubes). In further embodiments, the 5T gain cell is made of 2 FEOL transistors and 3 BEOL transistors. This allows for further scaling to achieve increased area savings. The two additional BEOL transistors may include a write transistor with large band gap materials to reduce leakage and a read transistor with large mobility materials such as carbon nanotubes to achieve high speed.

Note that in describing various embodiments of the present disclosure, the polarity of the different transistors (i.e., FETs) in the respective gain cell circuits may be changed as long as the correct operation of the respective gain cell circuits are preserved. For example, read transistors may be n-type FETs and write transistors may be p-type FETs, or vice versa. For another example, the read and write transistors may be all n-type FETs or all p-type FETs. In preserving correct operation, polarity of signal lines (SL) may also be changed. For example, signal lines may be changed from high voltage (e.g., VDD) to low voltage (e.g., GND) or vice versa. Further, the gain cell circuits described herein have corresponding gain cell structures (or devices), and the terms gain cell circuits, gain cell structures, and gain cell structures may be used interchangeably.

Embodiments shown in the present disclosure are implemented with fin field-effect-effect transistors (FinFETs), but the present disclosure is not limited thereto. For example, the present disclosure may be implemented with gate-all-around (GAA) FETs. FinFETs refer to transistors having gate stacks (gate electrodes and gate dielectric layers) that form conducting channels on three sides of a fin structure. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein. For example, the present disclosure may also be implemented with planar MOSFETs.

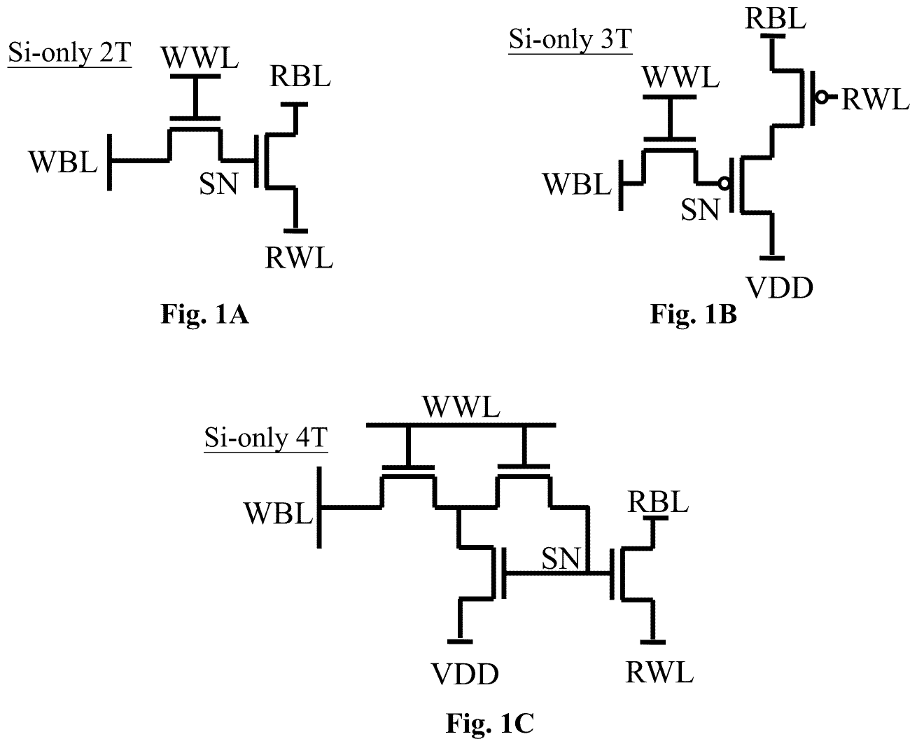

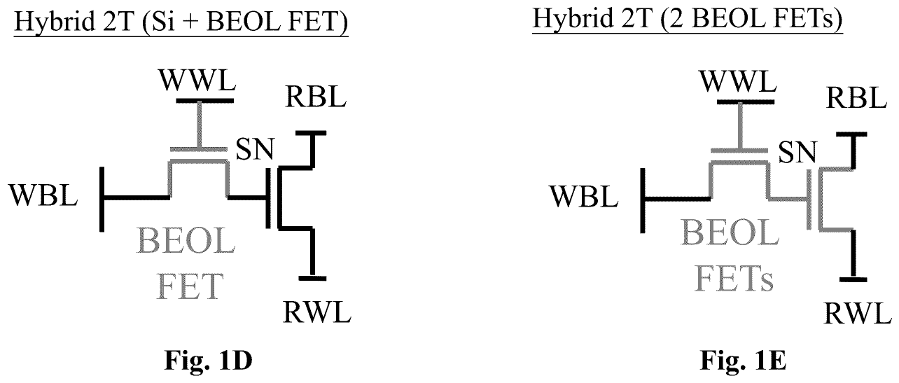

FIGS. 1A-1E illustrate gain cell circuits in various configurations, according to embodiments of the present disclosure. These gain cell circuits may also be referred to as embedded dynamic random-access memory (eDRAM). FIGS. 1A-1C illustrate silicon-only (Si-only) gain cell circuits, which refer to gain cell circuits with all of its transistors formed in the front-end-of-line (FEOL). FEOL generally refers to circuit regions and related processes that includes everything from a substrate (e.g., silicon wafer) up to but not including metal interconnect layers. These regions may include the substrate, active regions, source/drain features of active regions, channel regions of active regions, gate, and device-level metal features (e.g., device-level contacts and vias). The FEOL (or Si-only) transistors refer to transistors having active regions made of crystalline silicon or crystalline silicon germanium, which may be formed through epitaxial growth. For example, the Si-only transistors include source/drain epitaxial features doped with n-type or p-type dopants.

FIG. 1A illustrates a Si-only 2T gain cell circuit having a write transistor and a read transistor. The write transistor is coupled to the read transistor at a storage node (labeled SN) where data is written to or read from. The write transistor has a first terminal electrically connected to a write bit line (WBL), a gate terminal (or control terminal) electrically connected to a write word line (WWL), and a second terminal electrically connected to the storage node. The read transistor includes a first terminal coupled to a read bit line, a gate terminal (or control terminal) coupled to the storage node, and a second terminal coupled to the read word line (RWL). The first and second terminals of the different transistors may be also referred to first and second source/drain (S/D) features or S/D electrodes of the respective transistors.

FIG. 1B illustrates a Si-only 3T gain cell circuit having a write transistor and two read transistors. A first read transistor is coupled to a second read transistor in series. The first read transistor has a first terminal electrically connected to RBL, a gate terminal electrically connected to RWL, and a second terminal electrically connected to a first terminal of the second read transistor. The second read transistor has the first terminal, a gate terminal connected to a storage node (labeled SN), and a second terminal connected to signal line VDD. The write transistor is coupled to the second read transistor at the storage node where data is written to or read from. The write transistor has a first terminal electrically connected to WBL, a gate terminal electrically connected to WWL, and a second terminal electrically connected to the storage node. The first and second terminals of the different transistors may be also referred to first and second source/drain (S/D) features or S/D electrodes of the respective transistors. The 3T gain cell has advantages over the 2T gain cell due to extra read transistor for improving read access speeds.

FIG. 1C illustrates a Si-only 4T gain cell circuit having two write transistors, a feedback transistor, and a read transistor. The Si-only 4T gain cell circuit is similar to the Si-only 2T circuit and the similar features are not described again. The difference is in the addition of a second write transistor coupled to the first write transistor in series, and a feedback transistor coupled to the second write transistor and the read transistor to form a feedback loop. The gate terminals of the feedback transistor and the read transistor are electrically connected to a second terminal of the second write transistor at the storage node (labeled SN). The feedback transistor has a first terminal coupled to a shared terminal between the first and the second write transistors and a second terminal connected to a signal line VDD. The second write transistor has a first terminal coupled to the shared terminal of the first write transistor and the feedback transistor and the second terminal coupled to the storage node. The 4T gain cell has advantages over the 2T gain cell due to the transistors that make up the feedback loop to improve retention time at the storage node (SN) (e.g., extraneous or unwanted leakage signals can be driven to VDD through the feedback transistor instead of entering into the storage node).

FIGS. 1D-1E illustrate hybrid gain cell circuits, which refer to gain cell circuits with one or more transistor formed in the back-end-of-line (BEOL). BEOL generally refers to circuit regions and related processes outside of the FEOL. These regions may include the metal interconnect layers, backside of the substrate, or another wafer as part of a 3DIC structure. The BEOL transistors refer to transistors having active regions made of materials different from that of FEOL transistors. For example, instead of active regions made of crystalline silicon or silicon germanium, the BEOL transistors are made of different BEOL-compatible semiconductor materials such as amorphous silicon, amorphous oxides, two-dimensional materials, or carbon nanotubes. FIG. 1D illustrates a hybrid 2T (Si+BEOL FET) gain cell circuit where the write transistor is formed BEOL and the read transistor is formed FEOL. In other respects, the hybrid 2T gain cell circuit has same or similar configuration as the Si-only 2T gain cell circuit. FIG. 1E illustrates a hybrid 2T (2 BEOL FETs) gain cell circuit where both the read and write transistors are formed BEOL. In other respects, the hybrid 2T gain cell circuit has same or similar configuration as the Si-only 2T gain cell circuit. Hybrid gain cell circuits have advantages over the Si-only gain cell circuits due to improvements to cell density. For example, forming one or more transistors in BEOL may improve cell density by reducing area on FEOL. However, BEOL transistors generally perform more poorly than FEOL transistors due to lower carrier mobility and lower drive strength. This may adversely affect the threshold voltage variability of the read and write transistors if they are formed in BEOL.

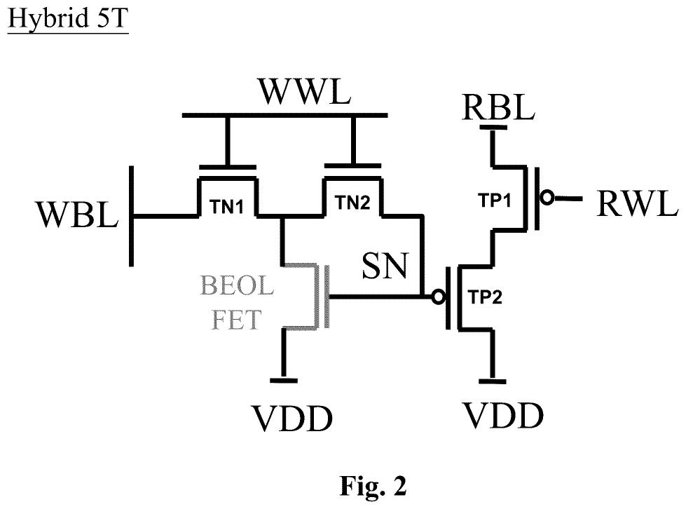

FIG. 2 illustrates a gain cell circuit having 5 transistors (5T) with 4 front-end-of-line (FEOL) transistors and 1 back-end-of-line (BEOL) transistor, according to an embodiment of the present disclosure. Compared to a 2 transistor gain cell (one transistor for read, one transistor for write), the 5T gain cell has an extra read and an extra write transistor to improve memory access and control. The 5T gain cell further includes a feedback transistor as part of a feedback loop to increase retention time, similar to the 4T gain cell circuit shown in FIG. 1C. The difference is, however, the feedback transistor is a BEOL FET. The electrical connections to WBL, WWL, RBL, RWL, and signal lines VDD (or GND) are not repeated for the sake of brevity.

By having the feedback transistor formed BEOL, device footprint on FEOL is reduced for device density benefits. Further, the BEOL feedback transistor may be formed to have a bigger area to increase storage node capacitance, which cannot be done in Si-only gain cells without increasing device footprint. Even further, the BEOL feedback transistor will not adversely affect critical read/write operations due to its relaxed requirements to leakage, variability, drive, and stability (i.e., the feedback transistor is for retaining charge and not performing read/write).

Still referring to FIG. 2, the hybrid 5T gain cell circuit includes a first write transistor TN1 and a second write transistor TN2 coupled in series, a first read transistor TP1 and a second read transistor TP2 coupled in series, and a BEOL feedback transistor formed in a layer above each of the transistors TN1, TN2, TP1, and TP2. The BEOL feedback transistor is electrically connected to a storage node SN, which is also electrically connected to a source/drain (S/N) terminal of the second write transistor TN2 and a gate terminal of the second read transistor TP2. In this embodiment, the transistors TN1, TN2, and BEOL FET are n-type transistors, and the transistors TP1 and TP2 are p-type transistors, although the polarity of all the transistors can be changed as long as correct operation is preserved. In this case, only one power rail (or signal line) VDD is needed, which has routing advantages over cases where two power rails (or signal lines) are needed (e.g., VDD and VSS (ground)).

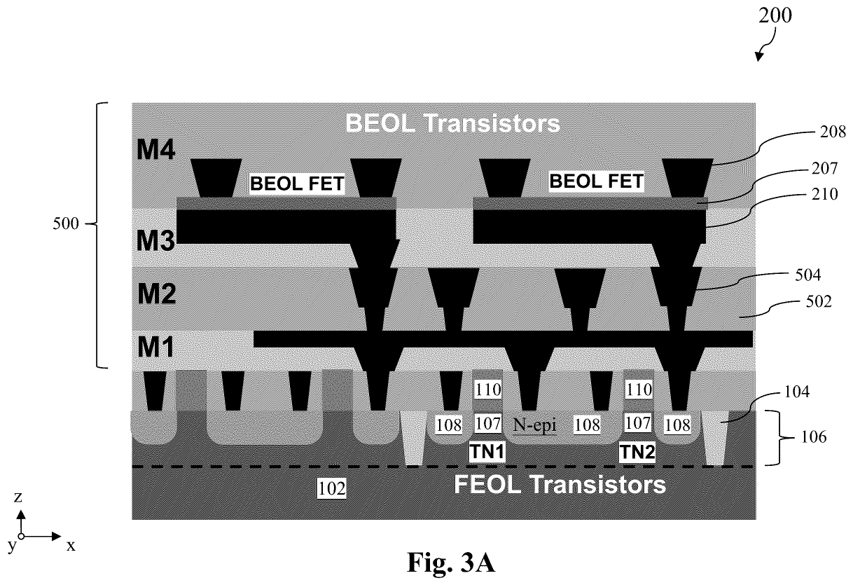

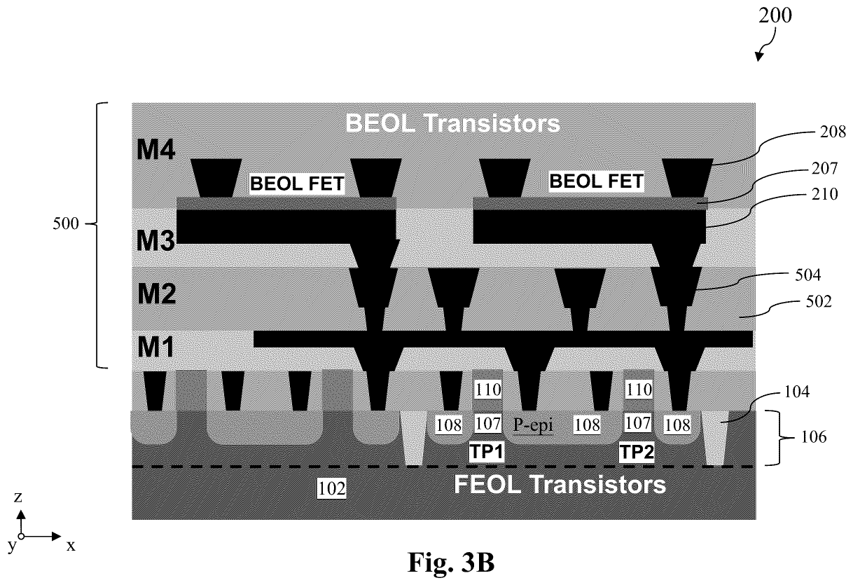

FIGS. 3A-3B illustrate simplified cross-sections of a gain cell structure 200 corresponding (at least in part) to the gain cell circuit of FIG. 2, according to an embodiment of the present disclosure. In the embodiment shown, FIG. 3A shows the transistors TN1, TN2, and the feedback transistor BEOL FET, and FIG. 3B shows the transistors TP1, TP2, and the feedback transistor BEOL FET. The transistors TN1 and TN2 are formed on an n-type active region 106 having N-epi features, and the transistors TP1 and TP2 are formed on a p-type active region 106 having P-epi features. The n-type active region 106 and p-type active region 106 extend parallel and lengthwise along the x direction and are adjacent to each other along the y direction (into and out of the page). Note that FIGS. 3A and 3B illustrate two gain cells adjacent to each other (each having the 5 transistors including the feedback transistor BEOL FET) but the present disclosure is not limited thereto. The feedback transistor BEOL FET may completely or partially cover the transistors TN1, TN2, TP1, and TP2; the larger size of the BEOL FET is beneficial for increasing storage node capacitance given the additional spacing in BEOL.

The gain cell structure 200 includes a substrate 102. The substrate 102 may be a silicon (Si) substrate, or a substrate having other semiconductor materials such as germanium (Ge), silicon carbide (SiC), silicon germanium (SiGe), or diamond. The substrate 102 may be doped with a p-type dopant such as boron or an n-type dopant such as phosphorus. Active regions 106 protrude above the substrate 102 and may include same or similar materials as the substrate 102. The active regions 106 may be formed by patterning the substrate 102 to form fin-shaped active regions 106 that protrude above a top surface of the substrate 102. For example, active regions 106 may be formed by a patterning process that includes lithography and etching. In some embodiments, a lithography process forms a patterned mask layer that covers regions of the substrate 102 for forming the active regions 106, and an etching process uses the patterned mask layer as an etch mask to etch exposed portions of the patterned mask layer. The etching process forms recesses that separate and define the active regions 106. The active regions 106 extend lengthwise along the x direction and may also be referred to as fin active regions or semiconductor fins.

Still referring to FIGS. 3A-3B, the gain cell structure 200 includes an isolation structure 104 disposed and formed over the substrate 102 and between active regions 106. The isolation structure 104 may be a shallow trench isolation (STI) layer and provides isolation between adjacent active regions 106 spaced along the x and y direction. The isolation structure 104 may be formed by any suitable processes, and the isolation structure 104 may include silicon oxide, silicon oxynitride, fluorine-doped silicate glass (FSG), a low-k dielectric, combinations thereof, and/or other suitable materials.

Still referring to FIGS. 3A-3B, the active regions 106 include channel regions 107 between source/drain (S/D) features 108, and metal gate stacks 110 (gate electrodes and gate dielectric layers) are disposed over and interfacing the channel regions 107. As shown, the FEOL transistors include the transistors TN1, TN2, TP1, and TP2, each defined by a gate stack 110 over a channel region 107 and S/D features 108 adjacent the channel region 107. The S/D features 108 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the active regions 106. Epitaxial S/D features 108 are doped with n-type dopants or p-type dopants. In some embodiments, for n-type transistors TN1 and TN2, the epitaxial S/D features 108 include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors TP1 and TP2, epitaxial S/D features 108 include silicon germanium or germanium and can be doped with boron, other p-type dopant, or combinations thereof (for example, forming Si:Ge:B epitaxial source/drain features). Each of the S/D features 108 may have S/D contacts (not labeled) disposed over them for electrical connections to upper level contacts. These S/D contacts along with the S/D features 108 may be collectively referred to as S/D features 108.

Still referring to FIGS. 3A-3B, the gain cell structure 200 further includes an interconnect structure 500 disposed over the FEOL transistors. The interconnect structure 500 includes interconnect metal lines and vias (collectively labeled as metal features 504) electrically connected to device level contacts such as the S/D features 108 and/or the gate stacks 110 according to desired gain cell circuit connections. The metal features 504 are formed within and embedded by dielectric features 502 (e.g., intermetal dielectric layers). In the depicted embodiment, the interconnect structure 500 includes intermetal layers M1-M4. Each intermetal layers M1-M4 may include a metal line layer and a via layer that vertically connects to the metal line layer. For example, in intermetal layer M1, there are M1 vias that vertically connects device level contacts to M1 metal lines, where the M1 metal lines extend lengthwise along the x direction; in intermetal layer M2, there are M2 vias that vertically connect M1 metal lines to M2 metal lines, where the M2 metal lines extend lengthwise along the y direction; in intermetal layer M3, there are M3 vias that vertically connect M2 metal lines to M3 metal lines, where the M3 metal lines extend lengthwise along the x direction; and so on. Some vias may vertically extend across multiple intermetal layers for direct connections (e.g., connecting between an M1 metal line and a M3 metal line).

As described in more detail below, the intermetal layer M1 may include the read word line (RWL) and the write word line (WWL); the intermetal layer M2 may include the read bit line (RBL), the read word line (RWL), and a high voltage line (VDD); and the intermetal layers M3 and M4 may include the feedback BEOL FETs. Each BEOL FET includes a BEOL gate 210, a semiconductor layer 207, and two S/D electrodes 208. As shown, the BEOL gate 210 may be a back gate formed in the intermetal layer M3, and the semiconductor layer 207 and S/D electrodes 208 may be formed in the intermetal layer M4 over the intermetal layer M3. The semiconductor layer is formed on the BEOL gate 210, and the S/D electrodes 208 are formed on opposite ends of the semiconductor layer 207. The semiconductor layer 207 may include BEOL-compatible materials such as amorphous silicon, amorphous oxides (e.g., IWO, ITO, IGZO, etc.), two-dimensional materials (WSe2, MoS2, WS2), carbon nanotubes, or low temperature Si, SiGe, or Ge.

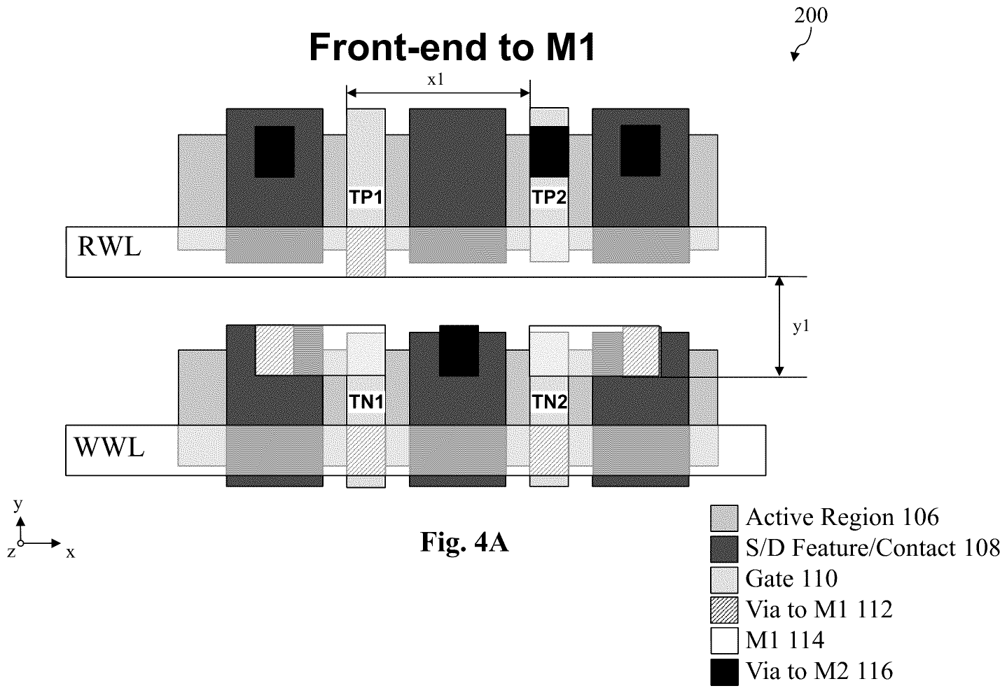

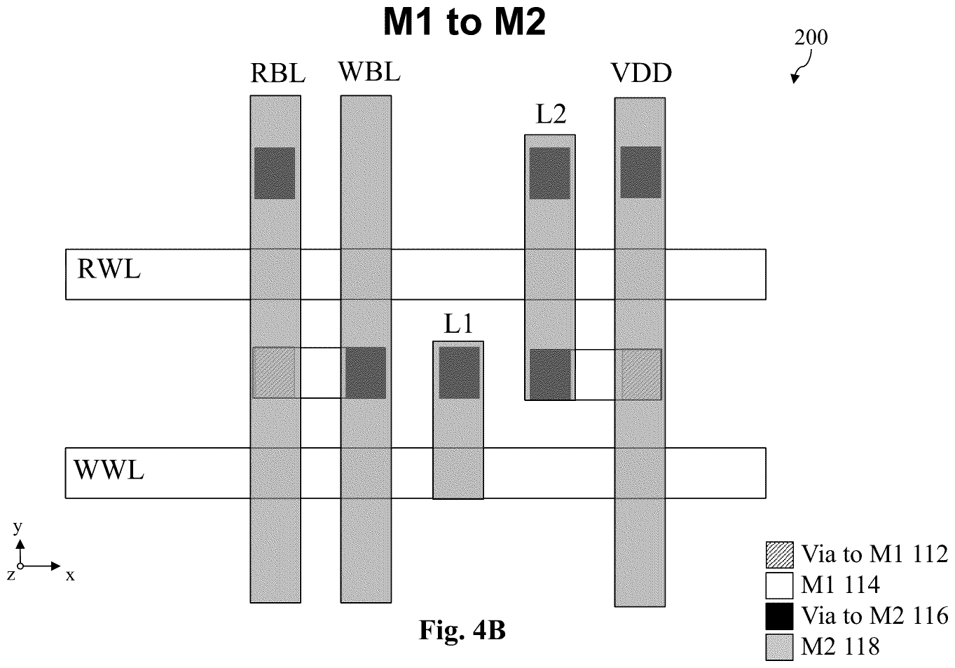

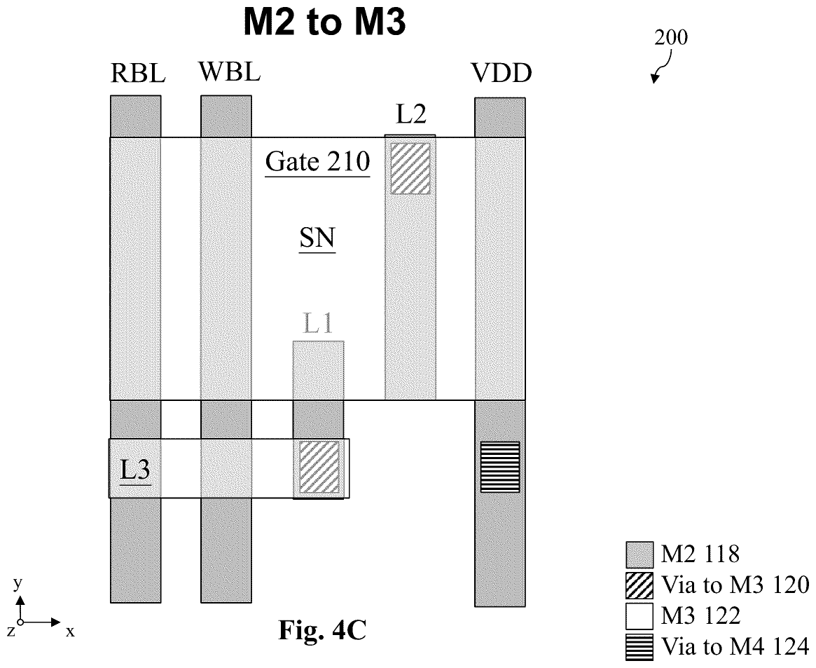

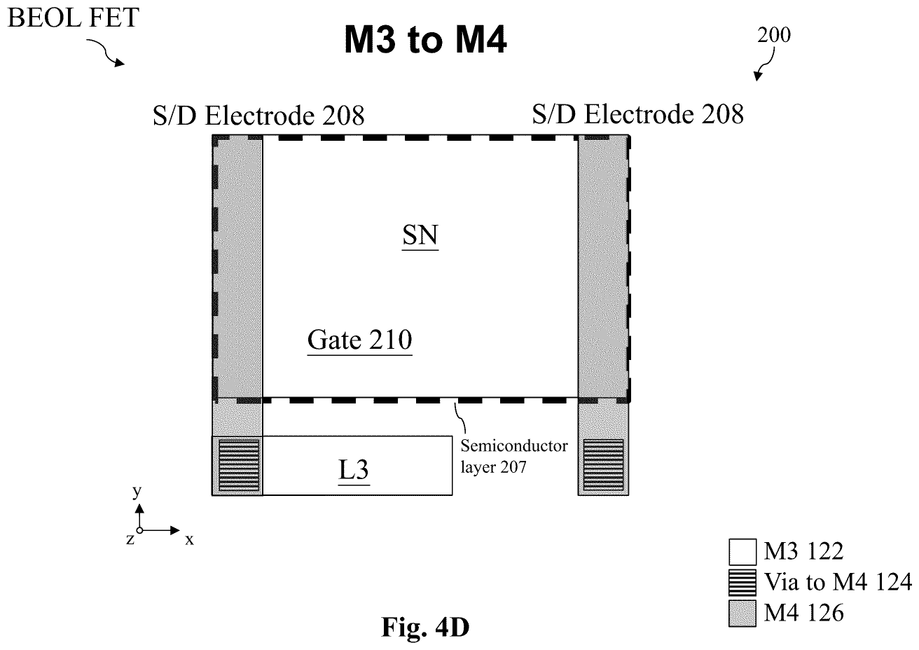

FIGS. 4A-4D illustrate top view layouts of a gain cell structure 200 at different layer levels (e.g., different layer levels of the gain cell circuit of FIG. 2 with cross-section of FIGS. 3A-3B), according to an embodiment of the present disclosure. FIGS. 4A-4D provide a layer-by-layer detailed view of how the gain cell circuit components of a gain cell structure 200 (e.g., as shown in FIGS. 3A-3B) are routed and laid out. The electrical connection of these gain cell circuit components are consistent with the gain cell circuit shown in FIG. 2. For ease of view, the intermetal dielectric layer surrounding and embedding the gain cell structure 200 is not shown.

FIG. 4A illustrate the gain cell structure 200 vertically spanning from the FEOL to the intermetal layer M1. The gain cell structure 200 includes two active regions 106 extending lengthwise along the x direction across the cell region. Each active region 106 include two gate stacks 110 extending lengthwise in the y direction over channel regions of the respective active regions 106. Adjacent the channel regions are S/D features/contacts 108. As shown, a first active region 106 (e.g., n-type active region) and its corresponding gate stacks 110 forms FEOL transistors TN1 and TN2 (labeled on their respective gate stacks 110), and a second active region 106 (e.g., p-type active region) and its corresponding gate stacks 110 forms FEOL transistors TP1 and TP2 (labeled on their respective gate stacks 110). The gain cell structure 200 has a FEOL gate pitch x1 that spans a distance between adjacent gate stacks 110.

Still referring to FIG. 4A, the gain cell structure 200 includes several M1 metal lines 114 over the FEOL transistors TN1, TN2, TP1, and TP2. The M1 metal lines 114 include a write word line (WWL) electrically connected to the gate 110 of the transistor TN1 through a via to M1 112. The WWL is also electrically connected to the gate 110 of the transistor TN2 through another via to M1 112. The M1 metal lines 114 further include a read word line (RWL) electrically connected to the gate 110 of the transistor TP1 through another via to M1 112. The M1 metal lines 114 further include M1 local interconnects electrically connected to one of respective S/D feature/contacts 108 of the transistors TN1 and TN2 through additional respective vias to M1 112. These M1 local interconnects may route signal to desired positions in the gain cell structure 200 such as above gate stacks 110 for better spacing when connecting to higher intermetal layers. As shown, the gain cell structure 200 also includes vias to M2 116 for routing components in the FEOL (e.g., S/D features/contacts 108 and gate stack 110) directly to metal lines in intermetal layer M2 and skipping the intermetal layer M1. As shown, there are vias to M2 116 landing on a shared S/D feature/contact 108 between transistors TN1 and TN2, landing on the gate stack 110 of the transistor TP2, and landing on respective far-side S/D feature/contacts 108 of the transistors TP1 and TP2. The gain cell structure 200 has a M1 pitch y1 that spans a distance between adjacent M1 metal lines 114.

FIG. 4B illustrate the gain cell structure 200 vertically spanning from the intermetal layer M1 to the intermetal layer M2. FIG. 4B overlays FIG. 4A, and components previously described will not be repeated again for the sake of brevity. As shown, the gain cell structure 200 includes several M2 metal lines 118 over the M1 metal lines 114. The M2 metal lines 118 include a read bit line (RBL) electrically connected to the respective S/D feature/contact 108 of transistor TP1 through the respective via to M2 116. The M2 metal lines 118 further include a write bit line (WBL) electrically connected to the respective S/D feature/contact 108 of transistor TN1 through a respective via to M2 116 landing on the respective M1 local interconnect. The M2 metal lines 118 further include a signal line (VDD) electrically connected to the respective S/D feature/contact 108 of transistor TP2 through the respective via to M2 116. The M2 metal lines 118 further include a M2 local interconnect L1 electrically connected to the shared S/D feature/contact 108 between transistors TN1 and TN2 through the respective via to M2 116. The M2 metal lines 118 further include a M2 local interconnect L2 electrically connecting the metal gate stack 110 of transistor TP2 to the far-end S/D feature/contact 108 of transistor TN2 through respective vias to M2 116.

FIG. 4C illustrate the gain cell structure 200 vertically spanning from the intermetal layer M2 to the intermetal layer M3. FIG. 4C overlays FIG. 4B, and components previously described will not be repeated again for the sake of brevity. As shown, the gain cell structure 200 includes several M3 metal lines 122 over the M2 metal lines 118. The M3 metal lines 122 include a gate 210 of a BEOL FET, the gate 210 also corresponds/connects to a storage node SN. The gate 210 may be referred to as a back gate and may span an area equal to or greater than 2 times the gate pitch x1 in the x direction and 3 times the M1 pitch y1 in the y direction. The gate 210 is electrically connected to the M2 local interconnect L2 through a via to M3 120. The M3 metal lines 122 further include a M3 local interconnect L3 electrically connecting to the M2 local interconnect L1 through a via to M3 120. These M3 local interconnect L3 may route signal to desired positions in the gain cell structure 200 such as above the read bit line (RBL) for better spacing when connecting to higher intermetal layers. As shown, the gain cell structure 200 also includes a via to M4 124 for routing the signal line (VDD) in the intermetal layer M2 directly to metal lines in intermetal layer M4 and skipping the intermetal layer M3.

FIG. 4D illustrate the gain cell structure 200 vertically spanning from the intermetal layer M3 to the intermetal layer M4. FIG. 4D overlays FIG. 4C, and components previously described will not be repeated again for the sake of brevity. As shown, the gain cell structure 200 includes several M4 metal lines 126 over the M3 metal lines 122. The M4 metal lines 126 include two S/D electrodes 208 on opposite ends of the gate 210 along the x direction. Between the S/D electrodes 208 and the gate 210 is a semiconductor layer 207 having BEOL compatible semiconductor materials as previously described. The gate 210, the semiconductor layer 207, and the two S/D electrodes 208 collectively form the BEOL FET (i.e., BEOL feedback transistor). One of the S/D electrodes 208 on one end is electrically connected to the M3 local interconnect L3 through a via to M4 124. And another one of the S/D electrodes 208 on the opposite end is electrically connected to the signal line VDD through the respective via to M4 124 shown in FIG. 4B.

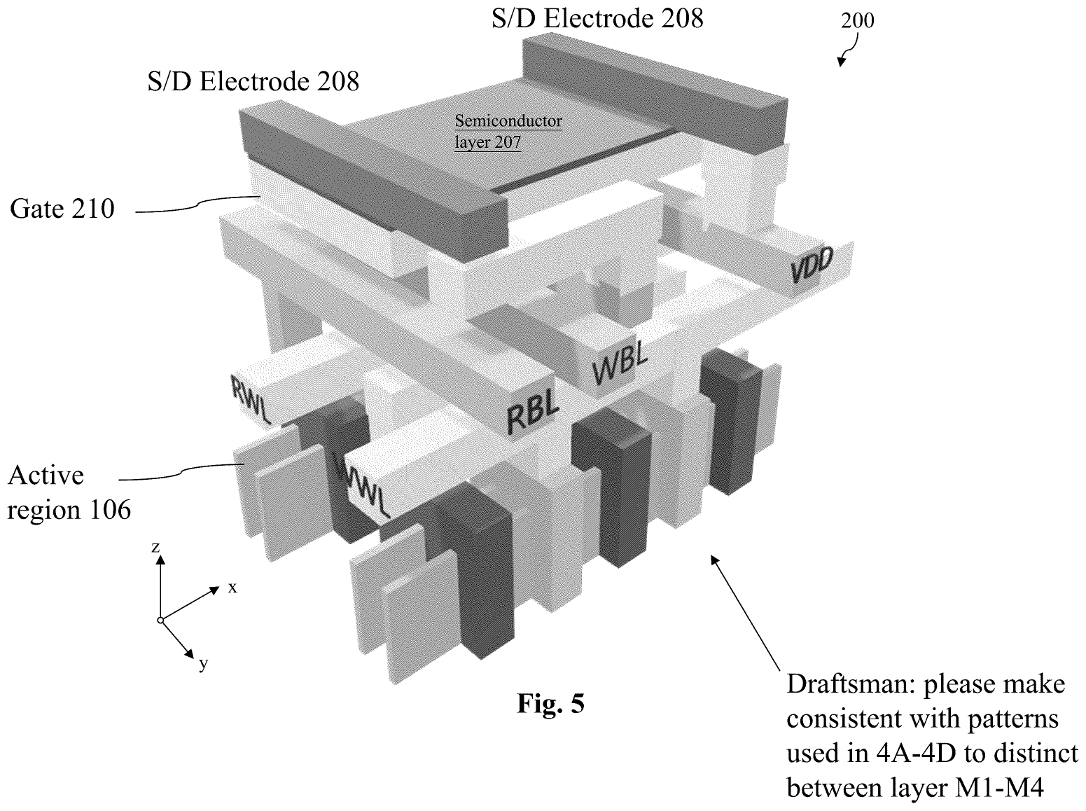

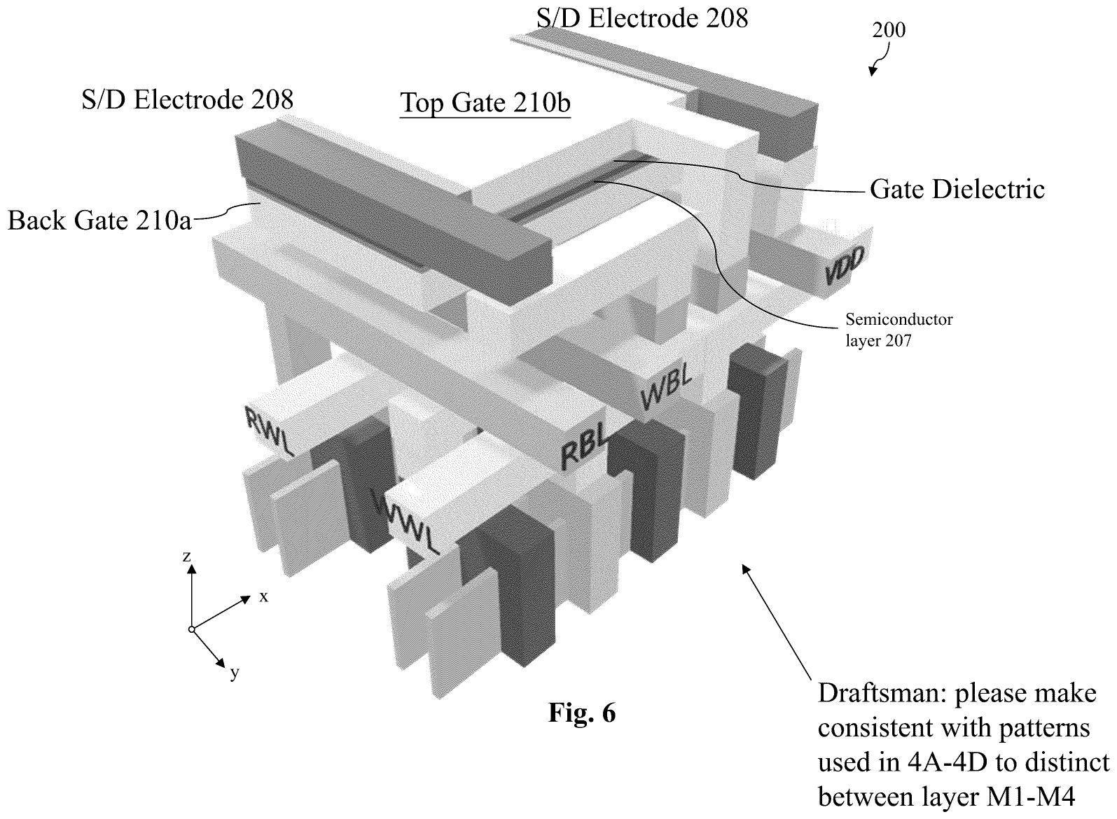

FIG. 5 illustrates a 3D perspective view of the gain cell structure 200 of FIGS. 4A-4D, according to an embodiment of the present disclosure. The perspective view is consistent with the top view layouts of FIGS. 4A-4D and shows all components of the gain cell structure 200 from the front-end level to the intermetal layer M4. In the embodiment shown, the FEOL transistors at the bottom may be formed in active regions 106 each having multiple fins; the RWL and WWL are over the active regions 106; the RBL, WBL, and VDD are formed over the RWL and WWL; and the feedback BEOL transistor having the gate 210, semiconductor layer 207, and the S/D electrodes 208 are formed over the RBL, WBL, and VDD. Although not shown in FIG. 5 (but shown in FIG. 6), a gate dielectric may be formed between the gate 210 and the semiconductor layer 207. The gate dielectric should be chosen to maximize the gate capacitance, while minimizing the gate leakage. Reasonable choices are high-K materials (e.g., HfO2) and with equivalent oxide thicknesses sub-1 nm.

FIG. 6 illustrates a 3D perspective view of the gain cell structure 200 of FIGS. 4A-4D, according to another embodiment of the present disclosure. FIG. 6 is similar to FIG. 5 and the similar features are not described again for the sake of brevity. The difference is that the gate 210 includes a back gate 210a (similar to the one shown in FIG. 5), but further includes a top gate 210b disposed laterally between the S/D electrodes 208 and over the semiconductor layer 207. In other words, the feedback BEOL transistor has a dual gate configuration for increased total capacitance. Additional metal routings (like as shown) may be configured to connect to the top gate 210b for proper operation. FIG. 6 also shows gate dielectric layers sandwiching the semiconductor layer 207 and interfacing with respective top and back gates 210a and 210b.

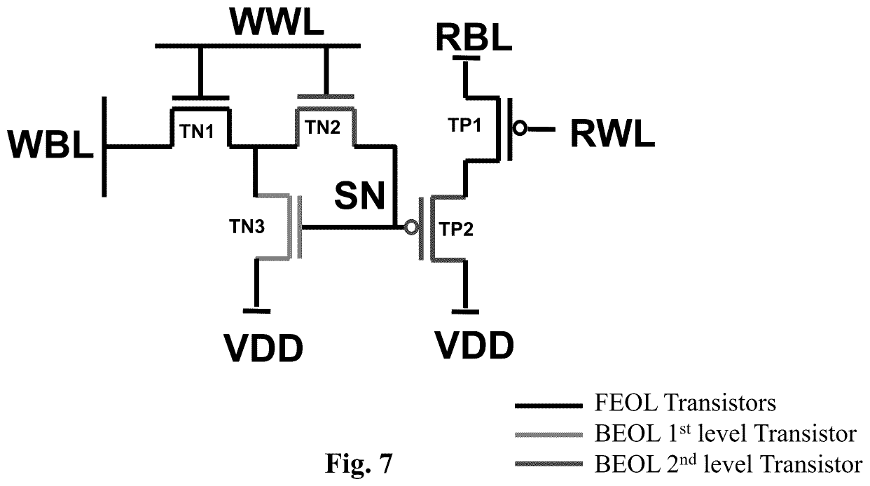

FIG. 7 illustrates a gain cell circuit having 5 transistors (5T) with 2 front-end-of-line (FEOL) transistors and 3 back-end-of-line (BEOL) transistor, according to an embodiment of the present disclosure. FIG. 7 resembles FIG. 2 except that the BEOL feedback transistor is labeled TN3 (e.g., an n-type transistor) and is a BEOL first level transistor, and the transistors TN2 and TP2 are second level BEOL transistors. As further illustrated in below figures, the BEOL first and second level transistors are disposed in different intermetal layers (e.g., second level is above first level). By moving the transistors TN2 and TP2 from the FEOL to the BEOL, cell density is further increased while preserving large retention time. In the embodiment shown, the transistors TN1 and TP1 remain FEOL transistors.

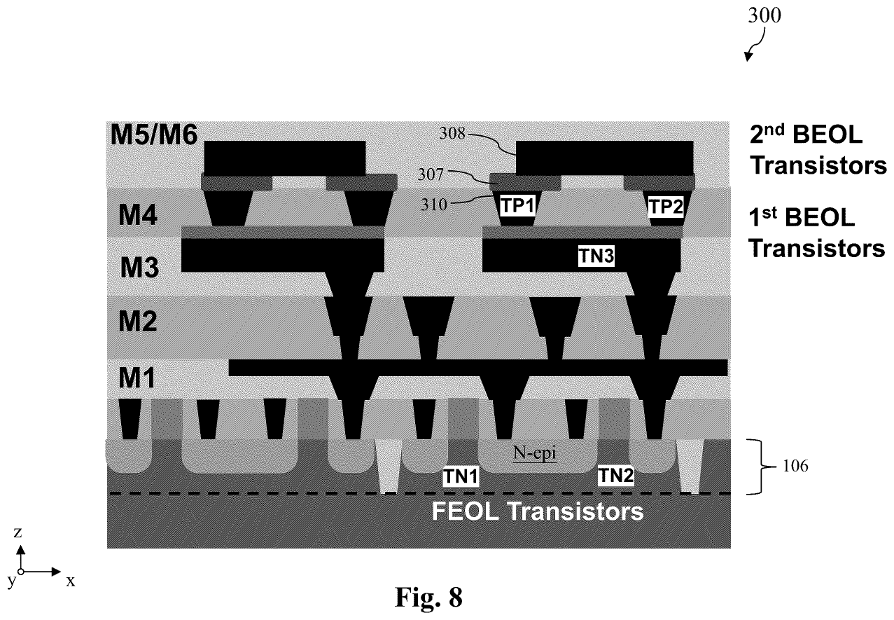

FIG. 8 illustrates a simplified cross-section of a gain cell structure 300 corresponding (at least in part) to the gain cell circuit of FIG. 7, according to an embodiment of the present disclosure. The gain cell structure 300 in FIG. 8 may resemble the gain cell structure 200 in FIGS. 3A-3B, and the similar features will not be described again for the sake of brevity. As shown, FIG. 8 shows FEOL transistors TN1 and TN2 formed on n-type active regions 106 having N-epi features; first level BEOL transistors TN3 (i.e., the feedback transistor) formed over the FEOL transistors TN1 and TN2; and second level BEOL transistors TP1 and TP2 formed over the first level BEOL transistors. Each of the second level BEOL transistors TP1 and TP2 may be formed in intermetal layers M5/M6 and includes a BEOL gate 310, a semiconductor layer 307 and a pair of S/D electrodes 308. These second level BEOL transistors may be structurally similar to the first level BEOL transistors (e.g., having a back gate) but spans a smaller area (e.g., spanning about half or smaller than half the area of the first level BEOL transistors). Compared to the gain cell structure 200 of FIGS. 3A-3B, the gain cell structure 300 of FIG. 8 illustrate a smaller cell footprint in the FEOL area, since for each gain cell, there are only two transistors formed therein (e.g., formed in a single n-type active region 106).

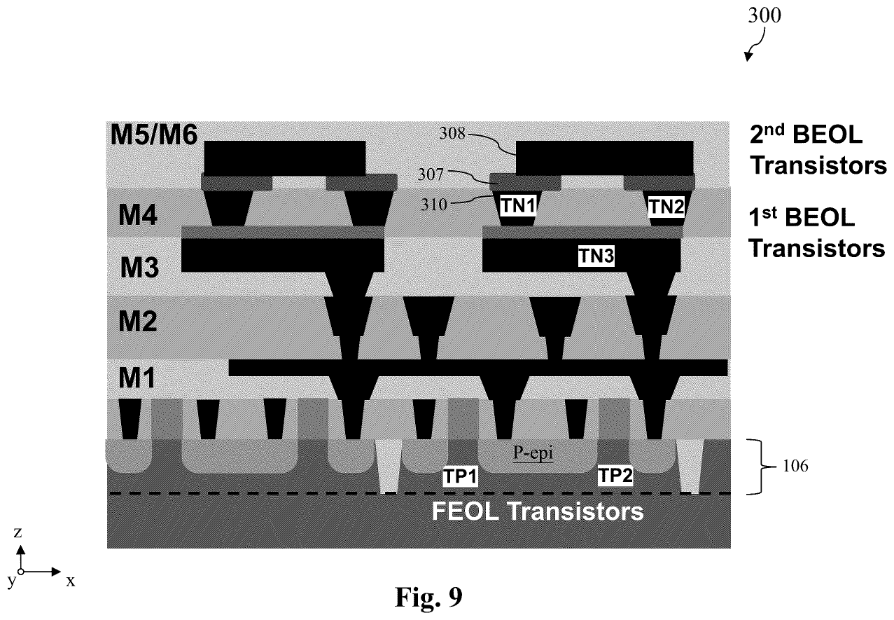

FIG. 9 illustrate simplified cross-sections of the gain cell circuit of FIG. 7, according to another embodiment of the present disclosure. The gain cell structure 300 in FIG. 9 may resemble the gain cell structure 300 in FIG. 8, and the similar features will not be described again for the sake of brevity. As shown, FIG. 9 shows FEOL transistors TP1 and TP2 formed on p-type active regions 106 having P-epi features; first level BEOL transistors TN3 (i.e., the feedback transistor) formed over the FEOL transistors TP1 and TP2; and second level BEOL transistors TN1 and TN2 formed over the first level BEOL transistors. Each of the second level BEOL transistors TN1 and TN2 may be formed in intermetal layers M5/M6 and includes a BEOL gate 310, a semiconductor layer 307 and a pair of S/D electrodes 308. These second level BEOL transistors may be structurally similar to the first level BEOL transistors but spans a smaller area (e.g., spanning about half or smaller than half the area of the first level BEOL transistors). Compared to the gain cell structure 200 of FIGS. 3A-3B, the gain cell structure 300 of FIG. 9 illustrate a smaller cell footprint in the FEOL area, since for each gain cell, there are only two transistors formed therein (e.g., formed in a single p-type active region 106).

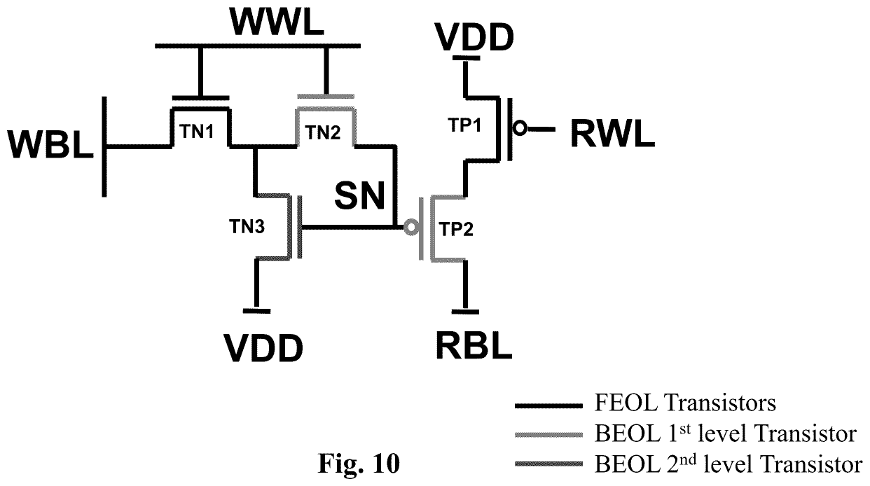

FIG. 10 illustrates a gain cell circuit having 5 transistors (5T) with 2 front-end-of-line (FEOL) transistors and 3 back-end-of-line (BEOL) transistor, according to another embodiment of the present disclosure. FIG. 10 resembles FIG. 7, except that the VDD node and the RBL node are flipped, and that the BEOL first and second level transistors are flipped. Connections of VDD and RBL can be optimized to trade-off gain cell retention time, noise during read operation, and gain cell bit cell area.

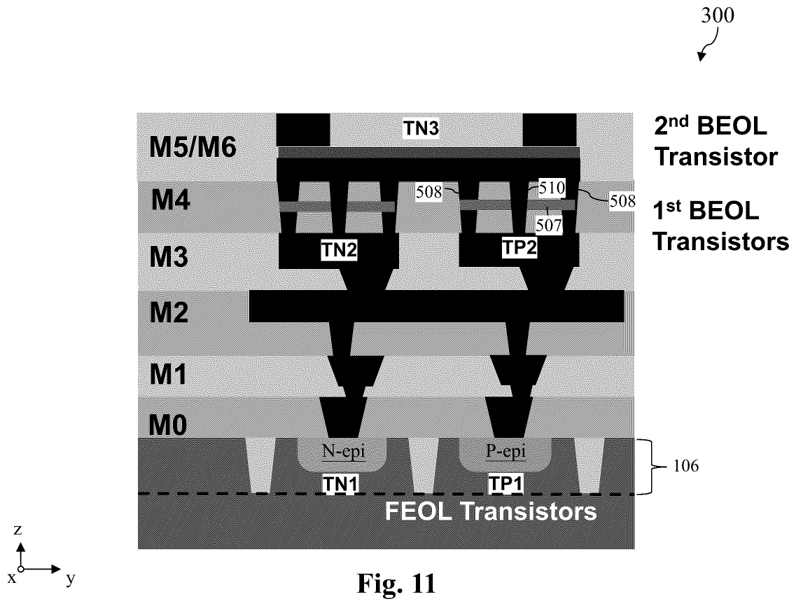

FIG. 11 illustrates a simplified cross-section of a gain cell structure 300 corresponding (at least in part) to the gain cell circuit of FIG. 10, according to an embodiment of the present disclosure. The gain cell structure 300 in FIG. 11 may resemble the gain cell structure 300 in FIGS. 8-9, and the similar features will not be described again for the sake of brevity. FIG. 11 illustrate a cross section cut across the y direction, therefore showing two adjacent active regions 106 extending lengthwise into or out of the page. As shown in the gain cell structure 300, one of the active region 106 is a n-type active region having N-epi S/D features, and the other one of the active region 106 is a p-type active region having P-epi S/D features. The FEOL transistor TN1 is formed in the n-type active region and the FEOL transistor TP1 is formed in the p-type active region. First level BEOL transistors TN2 and TP2 are formed over the FEOL transistors TN1 and TP1 in intermetal layers M3/M4, and a second level BEOL transistor TN3 (i.e., the feedback transistor) is formed over the first level BEOL transistors TN2 and TP2 in intermetal layers M5/M6. In the present embodiment, the first level BEOL transistors TN2 and TP2 may be structurally dissimilar to the second level BEOL transistor TN3. For example, the first level BEOL transistors TN2 and TP2 may be carbon nanotube transistors and each spanning a smaller area (e.g., spanning about half or smaller than half the area of the second level BEOL transistor). Each of the carbon nanotube transistors may include a semiconductor layer 507, a BEOL gate 510 over and wrapping channel portions of the semiconductor layer 507, and a pair of S/D electrodes 208 over and wrapping S/D portions of the semiconductor layer 507. Compared to the embodiments shown in FIGS. 8 and 9, the BEOL feedback transistor is flipped in vertical placement relative to the other BEOL transistors. And compared to the gain cell structure 200 of FIGS. 3A-3B, the gain cell structure 300 of FIG. 11 illustrate a smaller cell footprint in the FEOL area, since for each gain cell, there are only two transistors formed therein (e.g., formed in a p-type active region 106 and an adjacent n-type active region 106).

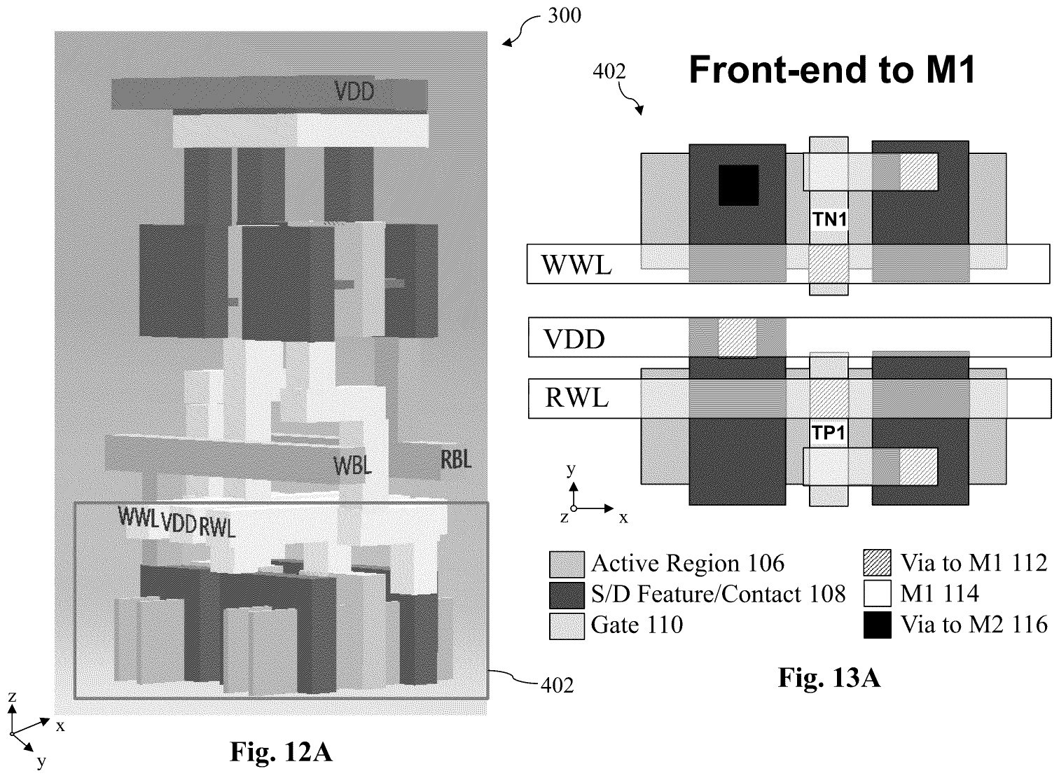

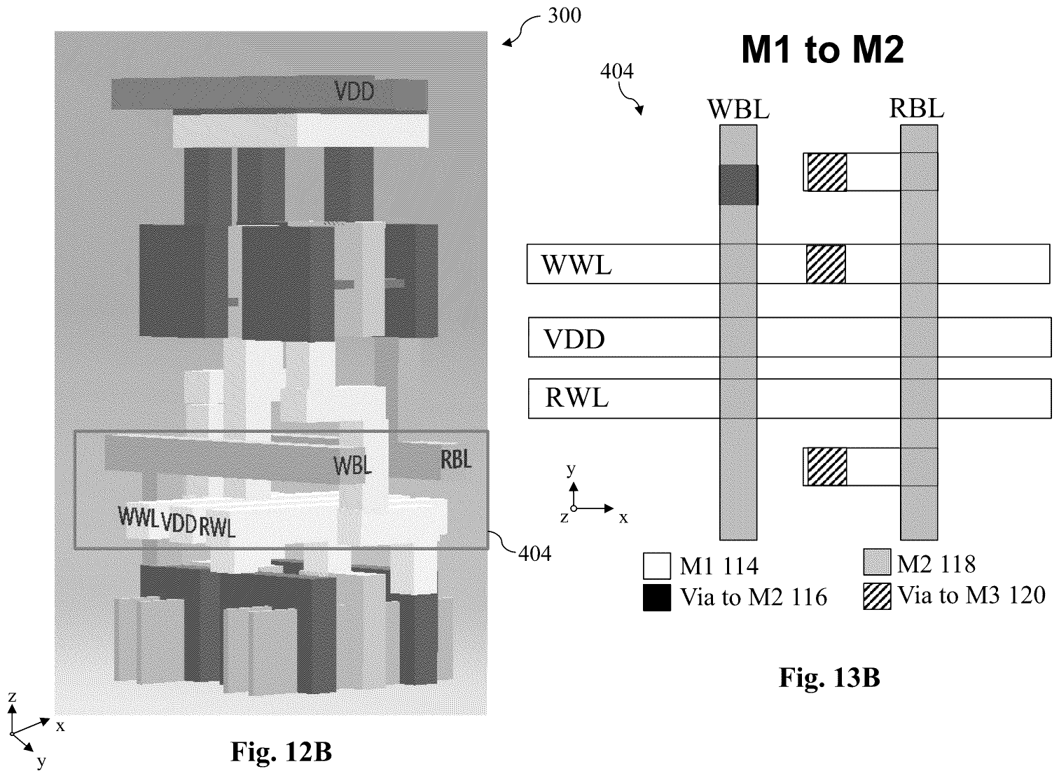

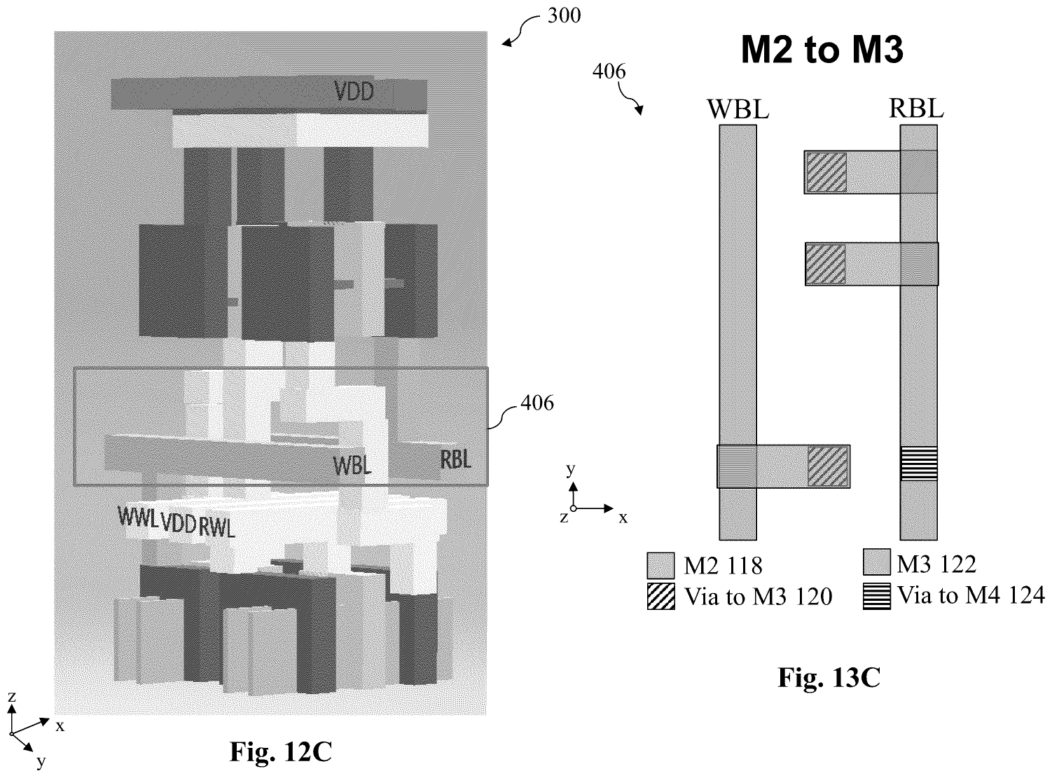

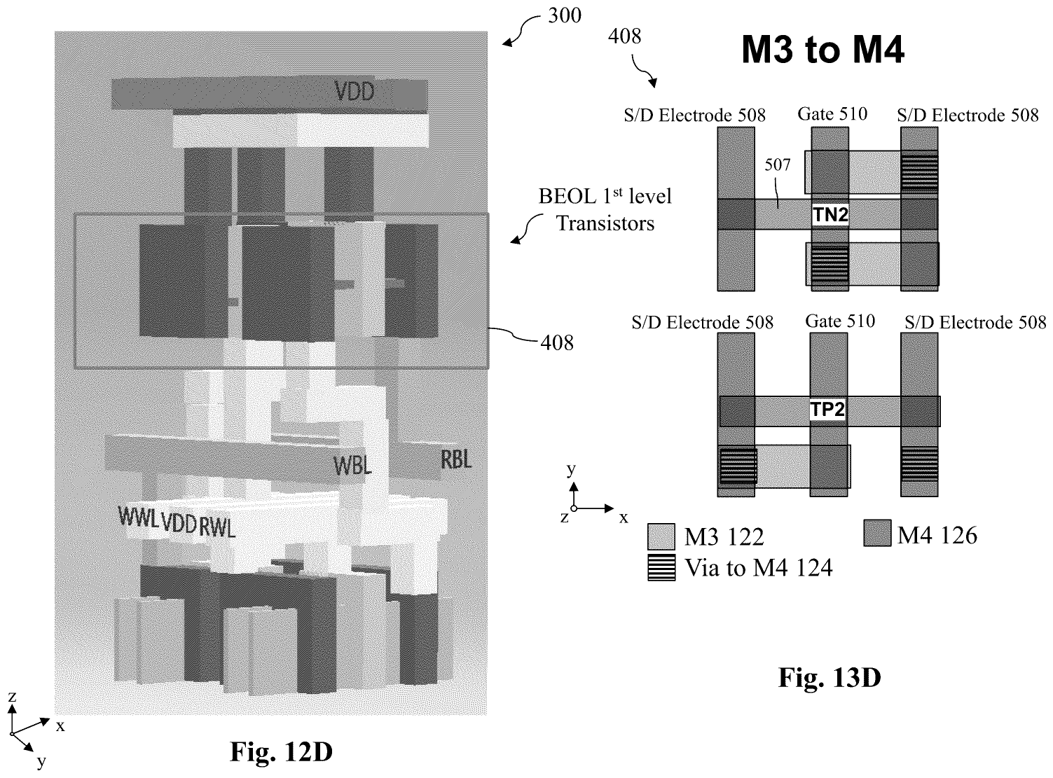

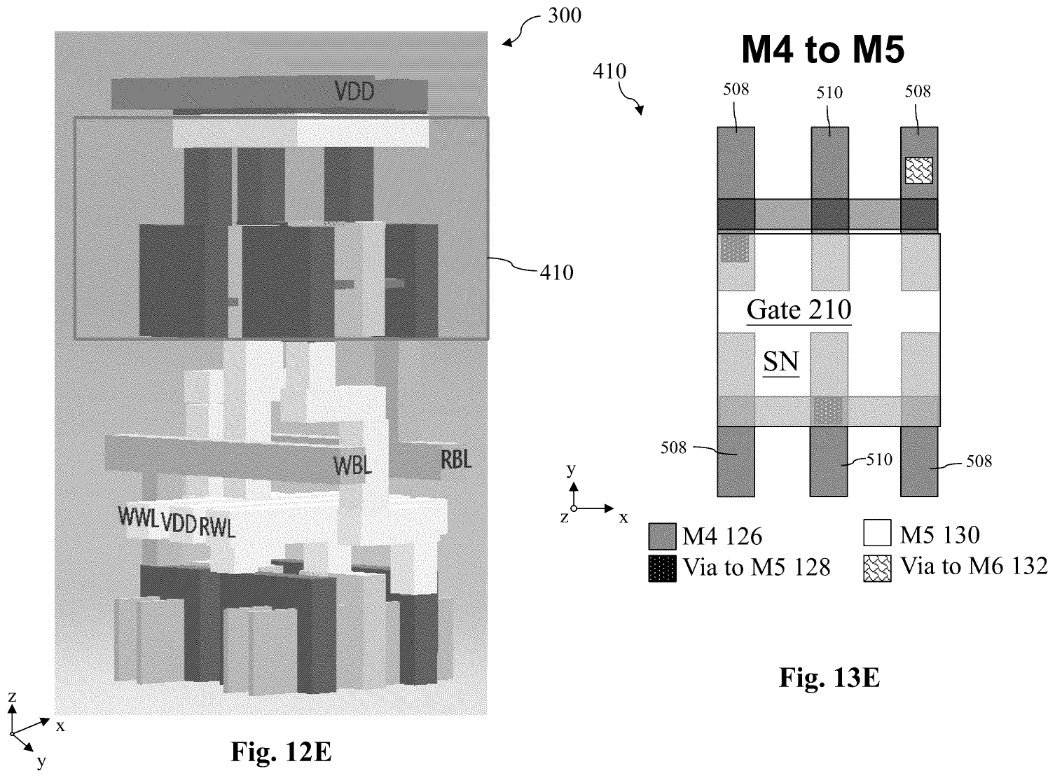

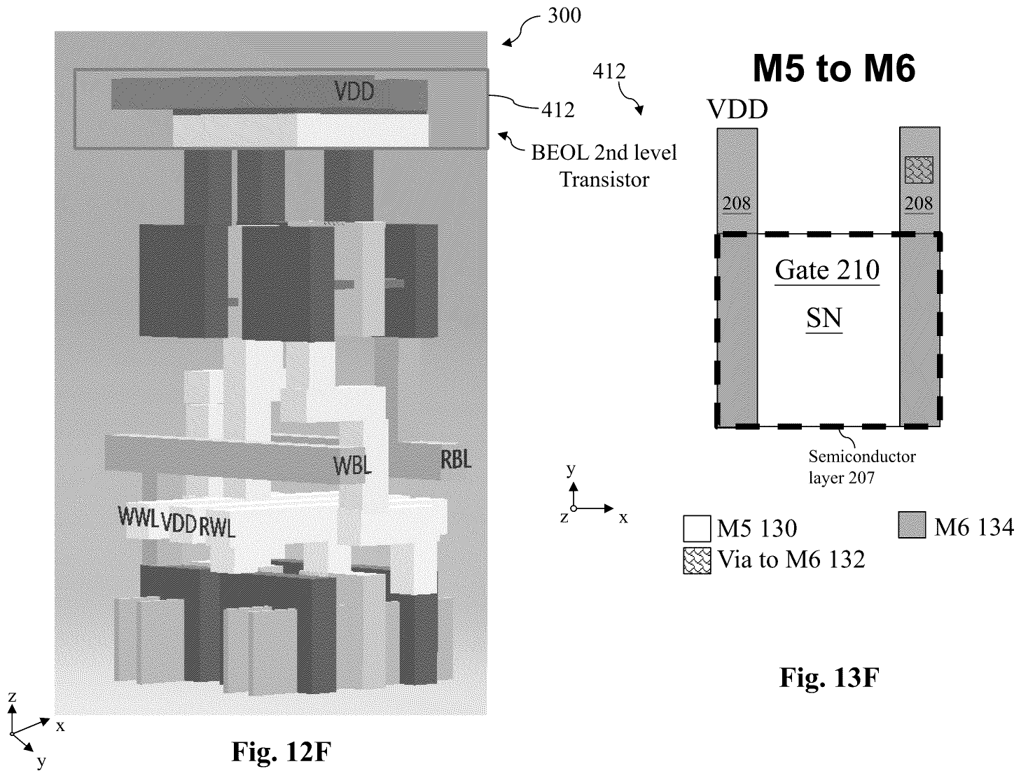

FIGS. 12A-12F illustrate 3D perspective views of a gain cell structure 300 (e.g., gain cell circuit of FIG. 10 with cross-section of FIG. 11), and with different layer levels highlighted in boxes 402, 404, 406, 408, 410, and 412, respectively, according to an embodiment of the present disclosure. FIGS. 13A-13F illustrate top view layouts of the gain cell structure 300 in FIGS. 12A-12F at the different layer levels highlighted in the boxes 402, 404, 406, 408, 410, and 412, respectively, according to an embodiment of the present disclosure. The electrical connection of the gain cell circuit components in gain cell structure 300 are consistent with the gain cell circuit shown in FIG. 10. For ease of view, the intermetal dielectric layer surrounding and embedding the gain cell structure 300 is not shown.

Referring now to FIGS. 12A and 13A collectively, the gain cell structure 300 in box 402 illustrate gain cell circuit components from the FEOL to the intermetal layer M1. In the FEOL, transistors TN1 and TP1 are formed on respective active regions 106 (e.g., a p-type and an n-type active region, respectively), each FEOL transistor having a respective gate stack 110 formed over a channel region and S/D feature/contacts 108 adjacent the channel region. The gain cell structure 300 includes several M1 metal lines 114 over the FEOL transistors TN1 and TP1. The M1 metal lines 114 include a write word line (WWL) electrically connected to the gate 110 of the transistor TN1 through a via to M1 112. The M1 metal lines 114 further include a read word line (RWL) electrically connected to the gate 110 of the transistor TP1 through another via to M1 112. The M1 metal lines 114 further include a signal line (VDD) electrically connected to an S/D feature/contact 108 of transistor TP1 through another via to M1 112. The M1 metal lines 114 further include M1 local interconnects electrically connected to one of respective S/D feature/contacts 108 of the transistors TN1 and TP1 through additional respective vias to M1 112. These M1 local interconnects may route signal to desired positions in the gain cell structure 200 such as above gate stacks 110 for better spacing when connecting to higher intermetal layers. As shown, the gain cell structure 200 also includes a via to M2 116 for routing components in the FEOL (e.g., S/D feature/contact 108) directly to metal lines in intermetal layer M2 and skipping the intermetal layer M1. As shown, a via to M2 116 lands on an S/D feature/contact 108 of transistor TN1.

Referring now to FIGS. 12B and 13B collectively, the gain cell structure 300 in box 404 illustrate gain cell circuit components from the intermetal layer M1 to the intermetal layer M2. FIG. 13B overlays FIG. 13A, and components previously described will not be repeated again for the sake of brevity. As shown, the gain cell structure 300 includes several M2 metal lines 118 over the M1 metal lines 114. The M2 metal lines 118 include a write bit line (WBL) electrically connected to the respective S/D feature/contact 108 of transistor TN1 through the via to M2 116. The M2 metal lines 118 further include a read bit line (RBL) overlaying the M1 metal lines 114 without making any electrical connections to the M1 metal lines. The gain cell structure 300 also includes vias to M3 120 for routing M1 metal lines directly to metal lines in intermetal layer M3 and skipping the intermetal layer M2. As shown, there is a via to M3 120 landing on the WWL, a via to M3 120 landing on one of the M1 local interconnects, and a via to M3 120 landing on another one of the M1 local interconnects.

Referring now to FIGS. 12C and 13C collectively, the gain cell structure 300 in box 406 illustrate gain cell circuit components from the intermetal layer M2 to the intermetal layer M3. FIG. 13C overlays FIG. 13B, and components previously described will not be repeated again for the sake of brevity. As shown, the gain cell structure 300 includes several M3 metal lines 122 over the M2 metal lines 118. The M3 metal lines include M3 local interconnects electrically connecting to the vias to M3 120, which as described previously, are electrically connected to a respective S/D feature/contact 108 of transistor TN1, a respective S/D feature/contact 108 of transistor TP1, and the WWL, respectively. These M3 local interconnect may route signal to desired positions in the gain cell structure 300 such as above the read bit line (RBL) and/or above the write bit line (WBL) for better spacing when connecting to higher intermetal layers.

Referring now to FIGS. 12D and 13D collectively, the gain cell structure 300 in box 408 illustrate gain cell circuit components from the intermetal layer M3 to the intermetal layer M4. FIG. 13D overlays FIG. 13C, and components previously described will not be repeated again for the sake of brevity. As shown, the gain cell structure 300 includes several M4 metal lines 126 over the M3 metal lines 122. As shown, the M4 metal lines 126 include S/D electrodes 208 and BEOL gates 510 for the BEOL first level transistors TN2 and TP2. Respective semiconductor layers 507 are formed between the intermetal layer M3 and M4 such that the semiconductor layers 507 are coupled to and wrapped around by the respective BEOL gates 510 and S/D electrodes 208. As such, the BEOL first level transistors TN2 and TP2 may be formed as carbon nanotube transistors, where the semiconductor layers 507 are carbon nanotubes. Note that the gain cell structure 300 further includes multiple vias to M4 124 that electrically connects respective underlying M3 local interconnects of the M3 metal lines 122 to the respective S/D electrodes 508 and gate 510.

Referring now to FIGS. 12E and 13E collectively, the gain cell structure 300 in box 410 illustrate gain cell circuit components from the intermetal layer M4 to the intermetal layer M5. FIG. 13E overlays FIG. 13D, and components previously described will not be repeated again for the sake of brevity. As shown, the gain cell structure 300 includes an M5 metal line 130 that correspond to the gate 210 of a second level BEOL transistor; the gate 210 also corresponds/connects to a storage node SN. The gate 210 is disposed over the intermetal layer M4 and may be similarly configured as the gate 210 described in FIG. 4C; however, in the gain cell structure 300, the gate 210 may span a smaller area because the gain cell area for the gain cell structure 300 is smaller having only two FEOL transistors at the bottom. The gate 210 is electrically connected to the gate 510 of the transistor TP2 through a via to M4 124. The gate 210 is further electrically connected to an S/D electrode 508 of the transistor TN2 through another via to M4 124. As shown, the gain cell structure 300 also includes a via to M6 132 for routing a respective S/D electrode 508 of the transistor TN2 in the intermetal layer M4 directly to metal lines in intermetal layer M6 and skipping the intermetal layer M5.

Referring now to FIGS. 12F and 13F collectively, the gain cell structure 300 in box 412 illustrate gain cell circuit components from the intermetal layer M5 to the intermetal layer M6. FIG. 13F overlays FIG. 13E, and components previously described will not be repeated again for the sake of brevity. As shown, the gain cell structure 300 includes several M6 metal lines 134 over the M5 metal line 130 (i.e., gate 210). The M6 metal lines 134 include two S/D electrodes 208 on opposite ends of the gate 210 along the x direction. Between the S/D electrodes 208 and the gate 210 is a semiconductor layer 207 having BEOL compatible semiconductor materials as previously described. The gate 210, the semiconductor layer 207, and the two S/D electrodes 208 collectively form the second level BEOL FET (i.e., BEOL feedback transistor). One of the S/D electrodes 208 on one end is electrically connected to the via to M6 132. And another one of the S/D electrodes 208 on the opposite end is electrically connected to (or corresponds to) a signal line VDD. The signal line VDD may extend lengthwise in the y direction.

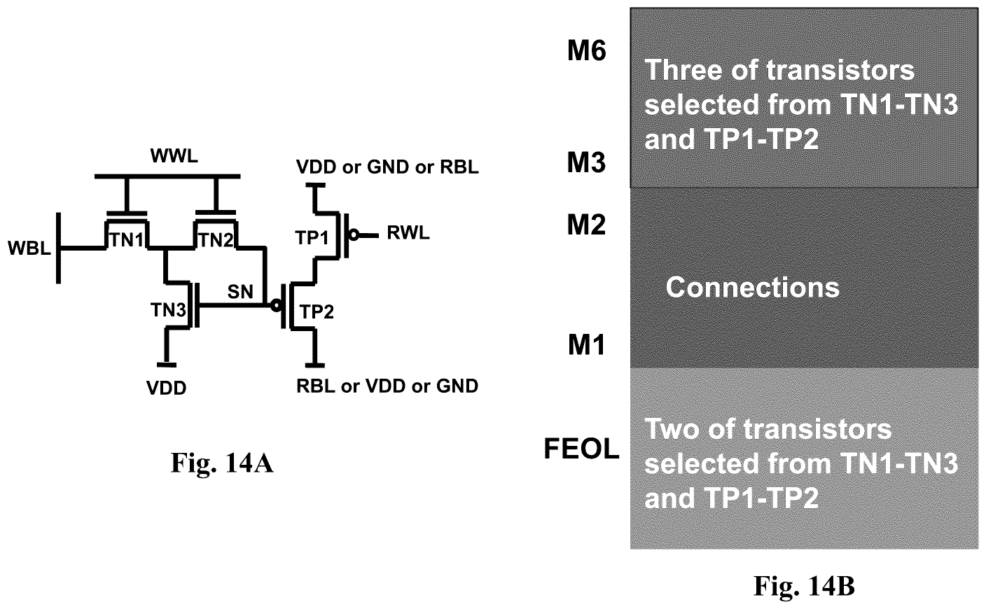

FIGS. 14A-14B illustrate a generalized gain cell circuit configuration having 5 transistors (5T) with 2 front-end-of-line (FEOL) transistors and 3 back-end-of-line (BEOL) transistor, according to an embodiment of the present disclosure. FIG. 14A illustrates a gain cell circuit that resembles the previously described 5T gain cell circuits of FIGS. 7 and 10, except that the FEOL transistors, the BEOL 1st level transistors, and the BEOL second level transistors are not explicitly identified. FIG. 14B corresponds to the gain cell circuit of FIG. 14A and illustrates different combination of transistor placements for the transistors TN1, TN2, TN3, TP1, and TP2 in a generalized cross-section. As shown, out of the 5 transistors: two transistors from TN1-TN3 and TP1-TP2 may be formed in the FEOL; the intermetal layers M1 and M2 may be used to form electrical routing connections through vias and metal lines; and three transistors from TN1-TN3 and TP1-TP2 may be formed in the BEOL.

However, for storage capacitance benefits, the transistor TN3 (feedback loop transistor) will be formed in the BEOL. In this case, the transistor TN3 will be formed above at least two of other read/write transistors (e.g., TN1, TN2, TP1, and/or TP2) and may span an area/space equal to the combined total of the area/space of these other read/write transistors. Further, the three BEOL transistors may be formed in two different intermetal layers, where the transistor TN3 is formed in one layer (e.g., M3/M4), and the other two transistors are formed in another layer above or below the one layer (e.g., M5/M6 or M3/M4). Further, one or more of the BEOL transistors may have vertical gates wrapping around a channel (e.g., carbon nanotube or other types of channels described herein) that extends between two S/D vertical electrodes, while one or more of the BEOL transistors may have a planar gate over a planar channel (e.g., amorphous oxide or 2D materials or other types of channels described herein) and two electrodes over ends of the planar gate. Further, the feedback BEOL transistor TN3 may span a greater area than the other BEOL transistors and the FEOL transistors. In one example, the transistor TN3 may span an area/space equal to the combined total of the area/space of two or more of the other transistors.

In general embodiments, the three BEOL transistors may include any of the BEOL-compatible materials herein described, which may include low-dimensional (LDM) materials, 2D materials, carbon nanotubes (CNTs), amorphous oxides, amorphous silicon, large band gap materials, etc. For example, the three BEOL transistors include: the transistor TN3 having LDM materials, the transistor TP2 having CNTs, and the transistor TN2 having 2D materials or CNTs.

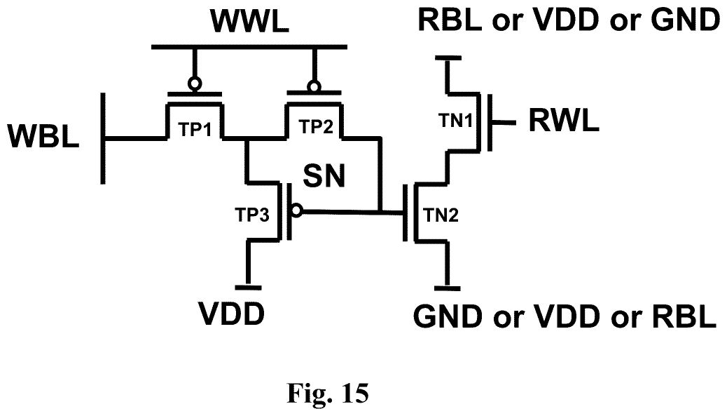

FIG. 15 illustrates a gain cell circuit having 5 transistors (5T) with 2 front-end-of-line (FEOL) transistors and 3 back-end-of-line (BEOL) transistor, according to another embodiment of the present disclosure. FIG. 15 resembles FIG. 14A but illustrates an alternative gain cell circuit with changed polarity-PFETs for write circuit portion (i.e., transistors TP1, TP2, and TP3) and NFETs for read circuit portion (i.e., transistors TN1 and TN2) while keeping correct gain cell operation.

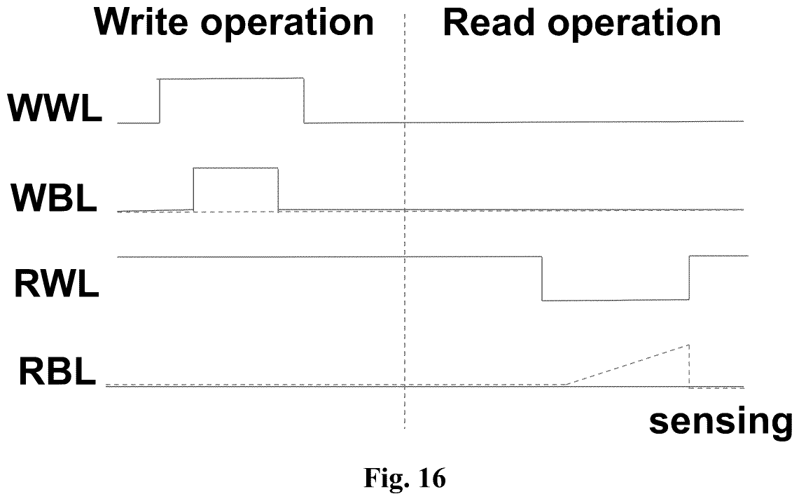

FIG. 16 illustrates operations of a gain cell, according to an embodiment of the present disclosure. As shown, a gain cell may perform write or read operations. During write operations, the read operation is turned off (e.g., RWL is biased high to turn off gate terminal of a p-type read transistor such as TP1), and the write operation is turned on (e.g., WWL is biased high to turn on gate terminals of n-type write transistors such as TN1 and TN2). During the write operation, the WBL may be biased high to store a bit into the storage node of the gain cell. During read operations, the write operation is turned off (e.g., WWL is biased low to turn off gate terminal of a n-type write transistors such as TN1 and TN2), and the read operation is turned on (e.g., RWL is biased low to turn on gate terminals of a p-type read transistor such TP1). During the read operation, the RBL may be biased high to read (or sense) a bit from the storage node of the gain cell.

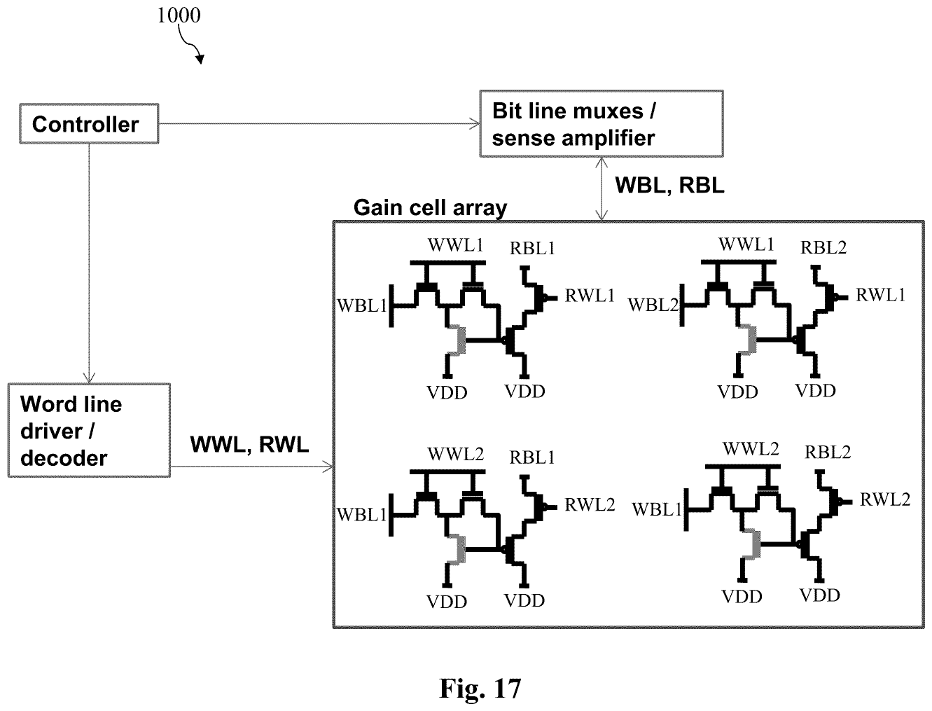

FIG. 17 illustrates a memory system 1000 having an array of 5T gain cells, according to an embodiment of the present disclosure. As shown, the gain cell array may comprise multiple 5T gain cells disposed in a matrix adjacent to each other in the x and/or y directions. Each of the 5T gain cells may have a gain cell structure 200 or 300 as described herein. Although not explicitly shown, adjacent gain cells may share same read word lines (e.g., RWL1 or RWL2) and write word lines (WWL1 or WWL2) that extend across gain cells along a first lateral direction, and adjacent gain cells may share same read bit lines (RBL1 or RBL2) and write bit lines (WBL1 or WBL2) that extend across gain cells along a second lateral direction perpendicular to the first lateral direction. The gain cells in the gain cell array may be addressed and controlled by bit line multiplexers (muxes) and/or sense amplifiers for bit lines (i.e., WBL, RBL); and addressed and controlled by word line drivers and/or decoders for word lines (i.e., WWL, RWL). A memory controller may provide input controls and instructions to the bit line muxes and/or sense amplifiers, and the word line driver and/or decoder, for proper selection of gain cells for performing gain cell read/write operations.

Although not limiting, the present disclosure offers advantages for configuring gain cell circuits, and particularly to gain cell circuits having 5 transistors (5T). The gain cell circuit includes 5 transistors (5T) with two read transistors, two write transistors, and a feedback loop transistor. For area and charge retention benefits, at least the feedback loop transistor is formed in the BEOL. Being formed in the BEOL allows the 5T circuit to fit within a 4T footprint and allows the feedback loop transistor to have larger area for increased storage capacitance. Further, the BEOL transistor is not used to write/read and therefore would not incur performance penalties to driving current and threshold voltage variability. In further embodiments, the 5T gain cell is made of 2 FEOL transistors and 3 BEOL transistors. This allows for further scaling to achieve increased area savings. The two additional BEOL transistors may include a write transistor with large band gap materials to reduce leakage and a read transistor with large mobility materials such as carbon nanotubes to achieve high speed.

One aspect of the present disclosure pertains to a device. The device includes a first transistor and a second transistor coupled in series; a third transistor and a fourth transistor coupled in series; and a fifth transistor, a first terminal of the fifth transistor being coupled to each of a first terminal of the first transistor and a first terminal of the second transistor, and a control terminal of the fifth transistor being coupled to a second terminal of the second transistor at a storage node. A control terminal of the fourth transistor is coupled to the storage node, and at least one of the first to fifth transistors is located in a layer above another one of the first to fifth transistors.

In an embodiment, the first and the second transistors are configured to write data into the storage node, the third and the fourth transistors are configured to read the data from the storage node, and the fifth transistor is configured to provide a feedback loop between the storage node and the first terminal of the first and second transistors.

In an embodiment, the fifth transistor is located above each of the first, second, third, and fourth transistors.

In an embodiment, the second, fourth, and fifth transistors are located above each of the first and third transistors. In a further embodiment, the fifth transistor spans a greater area than each of the second and fourth transistors.

In an embodiment, each of the first, second, third, and fourth transistors includes first active regions, the fifth transistor includes a second active region, and the first active regions and the second active region have different semiconductor materials. In a further embodiment, the first active regions include crystalline silicon or crystalline silicon germanium, and the second active region includes amorphous oxides, two-dimensional materials, or carbon nanotubes.

In an embodiment, the first and the second transistors include n-type doped source/drain features, and the third and the fourth transistors include p-type doped source/drain features.

Another aspect of the present disclosure pertains to a device. The device includes a first write transistor and a second write transistor coupled in series; a first read transistor and a second read transistor coupled in series; and a feedback transistor, wherein a first terminal of the feedback transistor being coupled to each of a first terminal of the first and second write transistors, and a control terminal of the feedback transistor being coupled to a second terminal of the second write transistor at a storage node. A control terminal of the second read transistor is coupled to the storage node. The feedback transistor is located in a layer above one of the first and second write transistors or one of the first and second read transistors.

In an embodiment, the feedback transistor includes: a back gate disposed above the first and the second read and write transistors; a semiconductor layer on the back gate; and first and second source/drain (S/D) electrodes on opposite ends of the semiconductor layer, wherein the back gate is electrically connected to the control terminal of the feedback transistor.

In a further embodiment, the semiconductor layer of the feedback transistor includes amorphous oxides or two-dimensional materials.

In a further embodiment, each of the first read and write transistors and the second read and write transistors include: a channel region; source/drain epitaxial features adjacent the channel region; and metal gate stacks over and interfacing the channel region. The back gate spans a greater area than each of the metal gate stacks.

In a further embodiment, the device further includes first metal lines having: a read word line over and electrically connected to a control terminal of the first read transistor; and a write word line over and electrically connected to control terminals of the first and the second write transistors. In a further embodiment, the device further includes second metal lines over and extending perpendicular to the first metal lines, the second metal lines having: a read bit line over and electrically connected to a first terminal of the first read transistor; and a write bit line over and electrically connected to a second terminal of the first write transistor. In a further embodiment, the device further includes third metal lines over the second metal lines, and the third metal lines include the back gate. In a further embodiment, the device further includes fourth metal lines over the third metal lines, and the fourth metal lines include the first and second source/drain (S/D) electrodes.

Another aspect of the present disclosure pertains to a structure. The structure includes an array of memory gain cells having first transistors formed on a semiconductor substrate; a first layer over the first transistors, the first layer having write word lines and read word lines electrically connected to one or more source/drain features of the first transistors; and a second layer over the first layer, the second layer having write bit lines and read bit lines electrically connected to another one of the one or more source/drain features of the first transistors. Each of the memory gain cells includes five transistors, the five transistors include: at least two of the first transistors; and a second transistor formed over the second layer, the second transistor having a gate structure covering an area equal to or greater than an area of the one or more first transistors; a semiconductor layer over the gate structure; and first and second source/drain (S/D) electrodes on opposite ends of the semiconductor layer. The gate structure of the second transistor is electrically connected to a storage node electrically connected to a source/drain feature of a write transistor and a gate structure of a read transistor.

In an embodiment, the five transistors include four first transistors and the second transistor is formed over the four first transistors.

In an embodiment, the five transistors includes: two first transistors; the second transistor formed over the two first transistors; and two third transistors formed over the second transistor.

In an embodiment, the five transistors includes: two first transistors; two third transistors formed over the two first transistors; and the second transistor formed over the two third transistors.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first transistor and a second transistor coupled in series;
a third transistor and a fourth transistor coupled in series; and
a fifth transistor, a first terminal of the fifth transistor being coupled to each of a first terminal of the first transistor and a first terminal of the second transistor, and a control terminal of the fifth transistor being coupled to a second terminal of the second transistor at a storage node,
wherein a control terminal of the fourth transistor is coupled to the storage node, and at least one of the first to fifth transistors is located in a layer above another one of the first to fifth transistors.

2. The device of claim 1, wherein the first and the second transistors are configured to write data into the storage node, the third and the fourth transistors are configured to read the data from the storage node, and the fifth transistor is configured to provide a feedback loop between the storage node and the first terminal of the first and second transistors.

3. The device of claim 1, wherein the fifth transistor is located above each of the first, second, third, and fourth transistors.

4. The device of claim 1, wherein the second, fourth, and fifth transistors are located above each of the first and third transistors.

5. The device of claim 4, wherein the fifth transistor spans a greater area than each of the second and fourth transistors.

6. The device of claim 1, wherein each of the first, second, third, and fourth transistors includes first active regions, the fifth transistor includes a second active region, and the first active regions and the second active region have different semiconductor materials.

7. The device of claim 6, wherein the first active regions include crystalline silicon or crystalline silicon germanium, and the second active region includes amorphous oxides, two-dimensional materials, or carbon nanotubes.

8. The device of claim 1, wherein the first and the second transistors include n-type doped source/drain features, and the third and the fourth transistors include p-type doped source/drain features.

9. A device, comprising:
a first write transistor and a second write transistor coupled in series;
a first read transistor and a second read transistor coupled in series; and
a feedback transistor, wherein a first terminal of the feedback transistor being coupled to each of a first terminal of the first and second write transistors, and a control terminal of the feedback transistor being coupled to a second terminal of the second write transistor at a storage node, wherein a control terminal of the second read transistor is coupled to the storage node,
wherein the feedback transistor is located in a layer above one of the first and second write transistors or one of the first and second read transistors.

10. The device of claim 9, wherein the feedback transistor includes:
a back gate disposed above the first and the second read and write transistors;
a semiconductor layer on the back gate; and
first and second source/drain (S/D) electrodes on opposite ends of the semiconductor layer, wherein the back gate is electrically connected to the control terminal of the feedback transistor.

11. The device of claim 10, wherein the semiconductor layer of the feedback transistor includes amorphous oxides or two-dimensional materials.

12. The device of claim 10, wherein each of the first read and write transistors and the second read and write transistors include:
a channel region;
source/drain epitaxial features adjacent the channel region;
and metal gate stacks over and interfacing the channel region,
wherein the back gate spans a greater area than each of the metal gate stacks.

13. The device of claim 10, further comprising first metal lines having:
a read word line over and electrically connected to a control terminal of the first read transistor; and
a write word line over and electrically connected to control terminals of the first and the second write transistors.

14. The device of claim 13, further comprising second metal lines over and extending perpendicular to the first metal lines, the second metal lines having:
a read bit line over and electrically connected to a first terminal of the first read transistor; and
a write bit line over and electrically connected to a second terminal of the first write transistor.

15. The device of claim 14, further comprising third metal lines over the second metal lines, and the third metal lines include the back gate.

16. The device of claim 15, further comprising fourth metal lines over the third metal lines, and the fourth metal lines include the first and second source/drain (S/D) electrodes.

17. A structure, comprising
an array of memory gain cells having first transistors formed on a semiconductor substrate;
a first layer over the first transistors, the first layer having write word lines and read word lines electrically connected to one or more source/drain features of the first transistors; and
a second layer over the first layer, the second layer having write bit lines and read bit lines electrically connected to another one of the one or more source/drain features of the first transistors,
wherein each of the memory gain cells includes five transistors, the five transistors include:
at least two of the first transistors; and
a second transistor formed over the second layer, the second transistor having a gate structure covering an area equal to or greater than an area of the one or more first transistors; a semiconductor layer over the gate structure; and first and second source/drain (S/D) electrodes on opposite ends of the semiconductor layer,
wherein the gate structure of the second transistor is electrically connected to a storage node electrically connected to a source/drain feature of a write transistor and a gate structure of a read transistor.

18. The structure of claim 17, wherein the five transistors include four first transistors and the second transistor is formed over the four first transistors.

19. The structure of claim 17, wherein the five transistors includes:
two first transistors;
the second transistor formed over the two first transistors; and
two third transistors formed over the second transistor.

20. The structure of claim 17, wherein the five transistors includes:
two first transistors;
two third transistors formed over the two first transistors; and
the second transistor formed over the two third transistors.
